(19) United States
(12) Patent Application Publication
(10) Pub. No.: US 2024/0312820 A1
(43) Pub. Date: Sep. 19, 2024

(54) SEMICONDUCTOR MANUFACTURING APPARATUS AND METHOD OF MANUFACTURING SEMICONDUCTOR DEVICE

(71) Applicant: Kioxia Corporation, Tokyo (JP)

(72) Inventor: Yoshio MIZUTA, Yokkaichi Mie (JP)

(21) Appl. No.: 18/595,341

(22) Filed: Mar. 4, 2024

(30) Foreign Application Priority Data
Mar. 17, 2023 (JP) 2023-043213

(51) Int. Cl. H01L 21/68; G03F 7/00; H01L 21/66; H01L 21/67; H01L 23/00; H01L 21/311; H01L 21/683

(52) U.S. Cl. CPC H01L 21/68; G03F 7/70775; H01L 21/67092; H01L 21/67288; H01L 22/20; H01L 24/80; H01L 21/31105; H01L 21/6838; H01L 24/05; H01L 24/08; H01L 2224/05647; H01L 2224/08145; H01L 2224/80123; H01L 2224/80357; H01L 2224/80379; H01L 2224/80896; H01L 2924/05042; H01L 2924/05442

(57) ABSTRACT

According to embodiments, a semiconductor manufacturing apparatus includes a control circuit configured to acquire, for a pair of substrates including a first substrate and a second substrate, a warp amount of the first substrate, the warp amount of the first substrate including an amount of protrusion of a portion of the first substrate relative to an edge of the first substrate; determine a desired size for a gap between the first and second substrates based on the acquired warp amount; and control a chuck movement device to move one of the first and second substrates to adjust the gap to the determined size before the first and second substrates are bonded.

### CROSS-REFERENCE TO RELATED APPLICATION

This application is based upon and claims the benefit of priority from Japanese Patent Application No. 2023-043213, filed on Mar. 17, 2023, the entire contents of which are incorporated herein by reference.

### FIELD

Embodiments described herein relate generally to a semiconductor manufacturing apparatus and a method of manufacturing a semiconductor device.

### BACKGROUND

Substrates cannot be appropriately bonded if at least one substrate is in a warped state.

### DESCRIPTION OF THE DRAWINGS

FIGS. 1A to 1C are sectional views illustrating a method of manufacturing a semiconductor device according to a first embodiment.

FIG. 2 is a plan view illustrating a configuration of a bonding apparatus according to the first embodiment.

FIG. 3 is a sectional view illustrating a configuration of a processing block according to the first embodiment.

FIG. 4 is a sectional view illustrating a configuration of an upper chuck and the like according to the first embodiment.

FIGS. 5A and 5B are sectional views illustrating a configuration of a lower chuck and the like according to the first embodiment.

FIGS. 6A to 6D are sectional views illustrating an operation of the bonding apparatus according to the first embodiment.

FIGS. 7A to 7D are sectional views illustrating a method of manufacturing an upper wafer according to the first embodiment.

FIG. 8 is a perspective view illustrating a configuration of an exposure apparatus according to the first embodiment.

FIGS. 9A to 9D are plan views illustrating exposure correction according to the first embodiment.

FIGS. 10A and 10B are sectional views illustrating exposure correction according to the first embodiment.

FIG. 11 is a plan view illustrating exposure correction according to the first embodiment.

FIG. 12 is a schematic view illustrating a flow of exposure and bonding according to a comparative example.

FIGS. 13A to 13E are sectional views illustrating details of bonding according to a comparative example.

FIG. 14 is a schematic view illustrating a flow of exposure and bonding according to a comparative example.

FIGS. 15A to 15E are sectional views illustrating details of bonding according to the first embodiment.

FIGS. 16A and 16B are graphs illustrating bonding correction according to the first embodiment.

FIGS. 17A and 17B are graphs illustrating bonding correction according to the first embodiment.

FIG. 18 is a schematic view illustrating a flow of exposure and bonding according to the first embodiment.

FIG. 19 is a table illustrating bonding correction according to the first embodiment.

FIGS. 20A to 20D are flowcharts illustrating a method of manufacturing the semiconductor device according to the first embodiment.

FIG. 21 is a block diagram illustrating a functional configuration of a control circuit according to the first embodiment.

FIG. 22 is a sectional view illustrating a method of manufacturing a semiconductor device according to a modification of the first embodiment.

### DETAILED DESCRIPTION

Embodiments provide a semiconductor manufacturing apparatus capable of appropriately bonding substrates and a method of manufacturing a semiconductor device.

In general, according to embodiments, a semiconductor manufacturing apparatus includes a control circuit configured to acquire, for a pair of substrates including a first substrate and a second substrate, a warp amount of the first substrate, the warp amount of the first substrate including an amount of protrusion of a portion of the first substrate relative to an edge of the first substrate; determine a desired size for a gap between the first and second substrates based on the acquired warp amount; and control a chuck movement device to move one of the first and second substrates to adjust the gap to the determined size before the first and second substrates are bonded.

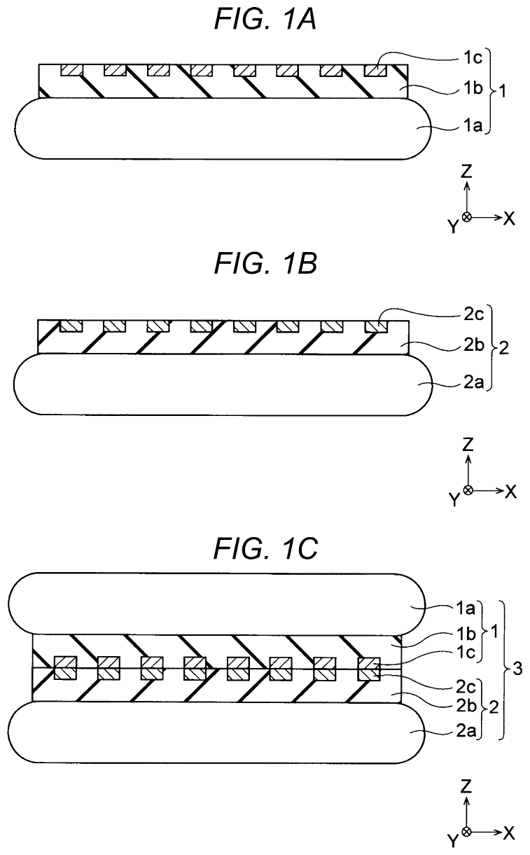

Hereinafter, embodiments will be described with reference to the drawings. In FIGS. 1A to 22, the same reference numerals are given to the same configurations and repeated description thereof will be omitted.

### First Embodiment

### (1) Bonding

FIGS. 1A to 1C are sectional views illustrating a method of manufacturing a semiconductor device according to a first embodiment.

The semiconductor device according to the embodiment is manufactured by bonding an upper wafer 1 illustrated in FIG. 1A and a lower wafer 2 illustrated in FIG. 1B. A wafer is more generally referred to herein as a substrate. FIG. 1C illustrates a bonded wafer 3 including the upper wafer 1 and the lower wafer 2 bonded to each other. The bonded wafer 3 is subsequently diced into a plurality of chips (also referred to herein as semiconductor devices).

In FIGS. 1A to 1C, X, Y, and Z directions (axes) perpendicular to each other are illustrated. In the present application, the +Z direction is referred to as an upper direction and the −Z direction is referred to as a lower direction. The −Z direction may match the direction of direction or may not match the direction of gravity.

As illustrated in FIG. 1A, the upper wafer 1 includes a wafer 1a, an interlayer insulating film 1b formed on the wafer 1a, and a plurality of metal pads 1c formed in the interlayer insulating film 1b. The wafer 1a is a semiconductor wafer such as a silicon (Si) wafer. The interlayer insulating film 1b is, for example, a stacked insulating film including a silicon oxide (SiO₂) film or a silicon nitride (SiN) film. The interlayer insulating film 1b may include various devices such as memory cell arrays and transistors or may include various conductive layers such as a wiring layer and a plug layer. The metal pads 1c are, for example, metal layers including copper (Cu).

As illustrated in FIG. 1B, the lower wafer 2 includes a wafer 2a, an interlayer insulating film 2b formed on the wafer 2a, and a plurality of metal pads 2c formed in the interlayer insulating film 2b. Materials and structures of the wafer 2a, the interlayer insulating film 2b, and the metal pads 2c are respectively similar to materials and structures of the wafer 1a, the interlayer insulating film 1b, and the metal pads 1c. For example, the upper wafer 1 includes a memory cell array and the lower wafer 2 includes a transistor that controls the memory cell array.

As illustrated in FIG. 1C, the bonded wafer 3 includes the lower wafer 2 and the upper wafer 1 disposed on the lower wafer 2. A direction of the upper wafer 1 illustrated in FIG. 1C is reverse to a direction of the upper wafer 1 illustrated in FIG. 1A. In FIG. 1C, the lower surface of the interlayer insulating film 1b is adhered to the upper surface of the interlayer insulating film 2b, and the lower surface of each metal pad 1c is bonded to the upper surface of the corresponding metal pad 2c.

When the semiconductor device according to the embodiment is manufactured, magnification of a pattern formed on the wafer 1a is not the same as magnification of a pattern formed on the wafer 2a in some cases. As used herein, “magnification” of a pattern is enlarging or reducing of the pattern, and such magnification is in the X and Y directions in FIG. 1C. For example, magnification of the metal pad 1c is not the same as magnification of the metal pad 2c in some cases. In these cases, there is concern of each metal pad 1c not appropriately bonding to the corresponding metal pad 2c, and there is concern of a bonding defect such as high resistance or short-circuiting of a joined portion occurring.

Accordingly, when the semiconductor device according to the embodiment is manufactured, a chuck holding the upper wafer 1 or the lower wafer 2 may be deformed in order to correct a difference in the magnification between the upper wafer 1 and the lower wafer 2. In this case, in the state in which the chuck is deformed, the upper wafer 1 and the lower wafer 2 are bonded. Accordingly, each metal pad 1c can be appropriately bonded to the corresponding metal pad 2c. For example, misalignment of about 0 to 10 parts per million (ppm) can be corrected. Further details of correction of the difference in the magnification will be described below.

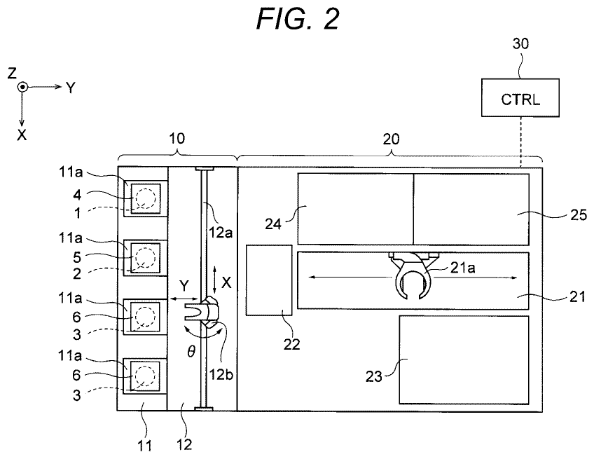

FIG. 2 is a plan view illustrating a configuration of a bonding apparatus according to the first embodiment. In the embodiment, the bonding apparatus bonds the upper wafer 1 and the lower wafer 2. The bonding apparatus is an example of the semiconductor manufacturing apparatus.

The bonding apparatus according to the embodiment includes a wafer transport device 10, a wafer processing device 20, and a control circuit 30, as illustrated in FIG. 2. The wafer transport device 10 transports the upper wafer 1 or the lower wafer 2 from the outside to the inside of a housing of the wafer processing device 20 or transports the bonded wafer 3 from the inside to the outside of the housing of the wafer processing device 20. The wafer processing device 20 performs various processes on the upper wafer 1, the lower wafer 2, and the bonded wafer 3 such as bonding the upper wafer 1 and the lower wafer 2. The control circuit 30 controls various operations of the bonding apparatus and controls, for example, conveyance of each wafer by the wafer transport device 10 or a process on each wafer by the wafer processing device 20.

The wafer transport device 10 includes a loading device 11 on which each wafer is loaded and a conveyance device 12 that conveys each wafer. The loading device 11 includes a plurality of loading stands 11a. The conveyance device 12 includes a conveyance path 12a and a conveyance robot 12b.

The loading stand 11a is used to load a cassette 4 in which the upper wafer 1 is placed, a cassette 5 in which the lower wafer 2 is placed, and a cassette 6 in which the bonded wafer 3 is placed. Two cassettes 6 illustrated in FIG. 2 are the cassette 6 in which a normal bonded wafer 3 is placed and the cassette 6 in which an abnormal bonded wafer 3 is placed.

The conveyance path 12a extends in the X direction. The conveyance robot 12b can be moved in the ±X direction along the conveyance path 12a or can be rotated in a ±θ direction in the Y-Z plane. The conveyance robot 12b can convey each wafer between the loading stand 11a located in the −Y direction and the wafer processing device 20 located in the +Y direction. Accordingly, each wafer can be transported to the inside of the housing or each wafer can be transported to the outside of the housing.

The wafer processing device 20 includes a conveyance block 21 in which each wafer is conveyed and processing blocks 22, 23, 24, and 25 in which various processes are performed on each wafer. The conveyance block 21 includes a plurality of conveyance robots 21a.

The conveyance robots 21a in the conveyance block 21 can convey each wafer between the wafer transport device 10 and the processing blocks 22 to 25. Devices in the processing block 22 move the upper wafer 1, the lower wafer 2, or the bonded wafer 3 in the ±Z direction. Devices in the processing block 23 refine the surface of the upper wafer 1 or the lower wafer 2. Devices in the processing block 24 hydrophilize the surface of the upper wafer 1 or the lower wafer 2. Devices in the processing block 25 bond the upper wafer 1 and the lower wafer 2.

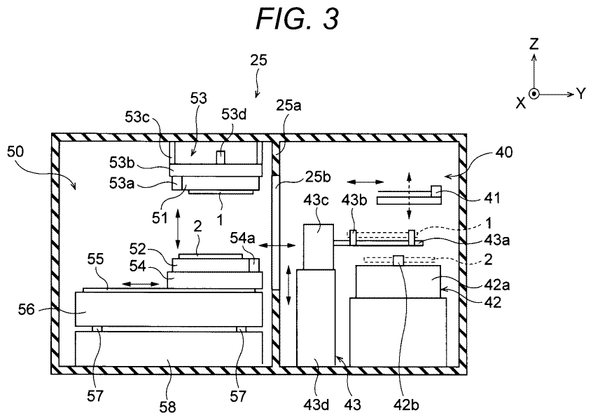

FIG. 3 is a sectional view illustrating a configuration of the processing block 25 according to the first embodiment.

The processing block 25 includes a conveyance chamber 40 and a bonding chamber 50 separated by an inner wall 25a of the processing block 25. The conveyance chamber 40 and the bonding chamber 50 communicate with an exit port 25b provided in the inner wall 25a. The conveyance chamber 40 is a chamber where each wafer is conveyed between the inside and the outside of the processing block 25. The bonding chamber 50 is a chamber where the upper wafer 1 and the lower wafer 2 are bonded.

The conveyance chamber 40 includes a conveyance module 41, a position adjustment module 42, and a reversing module 43. The position adjustment module 42 includes a base 42a and a detection device 42b. The reversing module 43 includes a holding arm 43a, a plurality of holding members 43b, a driving device 43c, and a column 43d.

The conveyance module 41 conveys each wafer along the X, Y, or Z axes. Specifically, the conveyance module 41 transports the upper wafer 1 or the lower wafer 2 from the outside to the inside of the bonding chamber 50 or transports the bonded wafer 3 from the inside to the outside of the bonding chamber 50.

The position adjustment module 42 adjusts a direction of a notch of each wafer. Specifically, in the position adjustment module 42, the base 42a supports a wafer, the detection device 42b detects a position of the notch of the wafer on the base 42a, and the base 42a rotates the wafer in accordance with the detected position of the notch. Accordingly, the direction of the notch is adjusted.

The reversing module 43 reverses a direction of the upper wafer 1. Specifically, in the reversing module 43, the holding members 43b on the holding arm 43a hold the upper wafer 1 and the holding arm 43a reverses the direction of the upper wafer 1. The holding arm 43a is supported by the column 43d via the driving device 43c and is driven by the driving device 43c. Accordingly, the direction of the upper wafer 1 is reversed. For example, when the metal pads 1c of the upper wafer 1 before the reversing are oriented in the +Z direction, the metal pads 1c of the upper wafer 1 after the reversing are oriented in the −Z direction.

The bonding chamber 50 includes an upper chuck 51, a lower chuck 52, an upper chuck support device 53, a lower chuck movement device 54, two rails 55 extending in the Y direction, a lower chuck movement device 56, two rails 57 extending in the X direction, and a loading stand 58. The upper chuck support device 53 includes an upper imaging device 53a, a support member 53b, a plurality of columns 53c, and a striker 53d, which is for example, a rod or stick-shaped device that pushes or presses another object. The lower chuck movement device 54 includes a lower imaging device 54a.

The upper chuck 51 is supported by the upper chuck support device 53 and holds the upper wafer 1 from the upper side. The upper chuck support device 53 is provided on a ceiling surface of a container of the processing block 25 and supports the upper chuck 51 from the upper side. Specifically, in the upper chuck support device 53, the upper chuck 51 is supported by the support member 53b and the support member 53b is supported by the column 53c. The upper imaging device 53a is provided in the support member 53b and images the lower wafer 2. Accordingly, a state of the lower wafer 2 is detected. The striker 53d is provided in the support member 53b and pressurizes the upper wafer 1 by pushing downward on the upper wafer 1. Accordingly, the upper wafer 1 and the lower wafer 2 are bonded.

The lower chuck 52 is supported by the lower chuck movement device 54, the rails 55, the lower chuck movement device 56, the rails 57, and the loading stand 58 and holds the lower wafer 2 from the lower side. The lower chuck movement device 54, the rails 55, the lower chuck movement device 56, the rails 57, and the loading stand 58 are provided on a floor of a container of the processing block 25 and support the lower chuck 52 from the lower side. The lower chuck movement device 54 is moved on the rails 55 provided in the lower chuck movement device 56 to be able to move the lower chuck 52 in the ±Y direction. The lower chuck movement device 56 is moved on the rails 57 provided in the loading stand 58 to be able to move the lower chuck 52 in the ±X direction. Further, the lower chuck movement device 54 is moved in the ±Z direction, is adjusted a tilt, and is rotated in the X-Y plane, and thus can elevate up or down or rotate the lower chuck 52. Accordingly, a gap between the upper wafer 1 and the lower wafer 2 can be increased or decreased. The lower imaging device 54a is provided in the lower chuck movement device 54 and images the upper wafer 1. Accordingly, a state of the upper wafer 1 is detected.

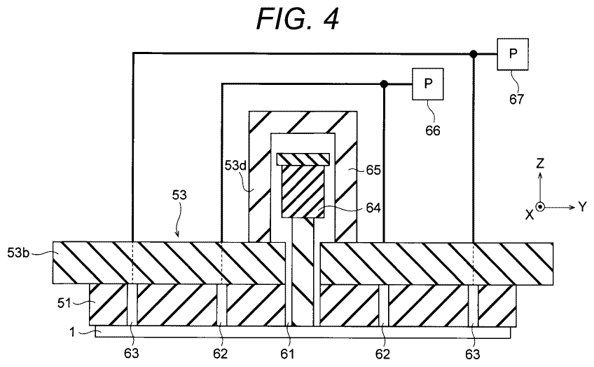

FIG. 4 is a sectional view illustrating a configuration of the upper chuck 51 and the like according to the first embodiment.

As illustrated in FIG. 4, the bonding chamber 50 according to the embodiment further includes a through via hole 61, a plurality of suction tubes 62, a plurality of suction tubes 63, an actuator 64, a cylinder 65, a vacuum pump 66, and a vacuum pump 67.

The through via hole 61 penetrates through the upper chuck 51 and the support member 53b. The actuator 64 and the cylinder 65 are provided in the striker 53d that pressurizes the upper wafer 1 by pushing downward on the upper wafer 1. Specifically, the cylinder 65 is provided on the support member 53b. The actuator 64 includes an upper portion provided in the cylinder 65 and a lower portion provided in the through via hole 61. When the upper portion of the actuator 64 is moved vertically in the cylinder 65, the lower portion of the actuator 64 is also moved vertically in the through via hole 61. As a result, the lower portion of the actuator 64 pressurizes the upper wafer 1 held by the upper chuck 51. The striker 53d according to the embodiment is driven by air supplied from a regulator (not illustrated).

The suction tubes 62 and 63 penetrate through the upper chuck 51 and are used to suck the upper wafer 1. The upper chuck 51 according to the embodiment holds the upper wafer 1 by sucking the upper wafer 1 using the suction tubes 62 and 63. The vacuum pumps 66 and 67 are respectively connected to the suction tubes 62 and 63 to vacuum the upper wafer 1 through the suction tubes 62 and 63. The upper wafer 1 is held through a vacuuming operation. In the bonding chamber 50 according to the embodiment, the vacuum pumps 66 and 67 can independently be driven.

In the bonding chamber 50 according to the embodiment, an upward force can be applied through the suction tubes 62 and 63 to the upper wafer 1 and a downward force can be applied by the actuator 64 (and the striker 53d) to the upper wafer 1. Further details of the forces will be described below.

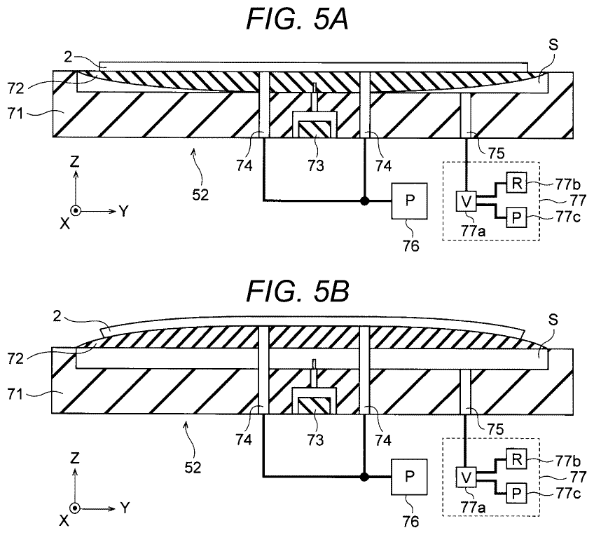

FIGS. 5A and 5B are sectional views illustrating a configuration of a lower chuck 52 and the like according to the first embodiment.

FIGS. 5A and 5B illustrate different states of the same lower chuck 52. Hereinafter, details of the lower chuck 52 will be described with reference to FIG. 5A. In the description, FIG. 5B is also appropriately referred to.

As illustrated in FIG. 5A, the lower chuck 52 according to the embodiment includes a base 71, a loading platform 72, a measurement device 73, a plurality of suction tubes 74, and a ventilation hole 75. The bonding chamber 50 according to the embodiment further includes a vacuum pump 76 and a deformation device 77 as components for the lower chuck 52. The deformation device 77 includes a switching valve 77a, a regulator 77b, and a vacuum pump 77c.

The base 71 supports the loading platform 72 on which the lower wafer 2 is loaded from the lower side. There is a space S between the base 71 and the loading platform 72. The loading platform 72 has a diameter greater than a diameter of the lower wafer 2 in a plan view. As illustrated in FIG. 5A, the loading platform 72 has a larger thickness at a center of the loading platform 72 and has a smaller thickness at a portion away from the center of the loading platform 72. The loading platform 72 is formed of, for example, a ceramic material.

The loading platform 72 can be deformed, as illustrated in FIGS. 5A and 5B. In the bonding chamber 50 according to the embodiment, the lower wafer 2 loaded on the loading platform 72 can be deformed by deforming the loading platform 72. Accordingly, it is possible to correct a difference in magnification between the upper wafer 1 and the lower wafer 2. In the bonding chamber 50 according to the embodiment, misalignment between the metal pads 1c and 2c can be corrected by bonding the upper wafer 1 and the lower wafer 2 in a state in which the lower wafer 2 is deformed by the loading platform 72. The loading platform 72 illustrated in FIG. 5A has a flat upper surface. As a result, the shape of the lower wafer 2 is also flat. The loading platform 72 illustrated in FIG. 5B has a curved upper surface in an upward convex form. As a result, the shape of the lower wafer 2 is also curved in an upward convex form.

The measurement device 73 is provided at a central portion of the base 71 to measure a displacement amount (deformation amount) of the loading platform 72. The suction tubes 74 penetrate through the base 71 and the loading platform 72 and are used to suck the lower wafer 2. The lower chuck 52 according to the embodiment holds the lower wafer 2 by sucking the lower wafer 2 through the suction tubes 74. The vacuum pump 76 is connected to the suction tubes 74 to vacuum the lower wafer 2 through the suction tubes 74. The lower wafer 2 is held through a vacuuming operation.

The ventilation hole 75 penetrates through the base 71 and is used to supply air into the space S or exhaust air from the space S. The deformation device 77 deforms the loading platform 72 by supplying air into the space S or exhausting air from the space S. Specifically, the deformation device 77 supplies air into the space S using the regulator 77b and exhausts air from the space S using the vacuum pump 77c. The switching between the air supply and the air exhaust is executed using the switching valve 77a.

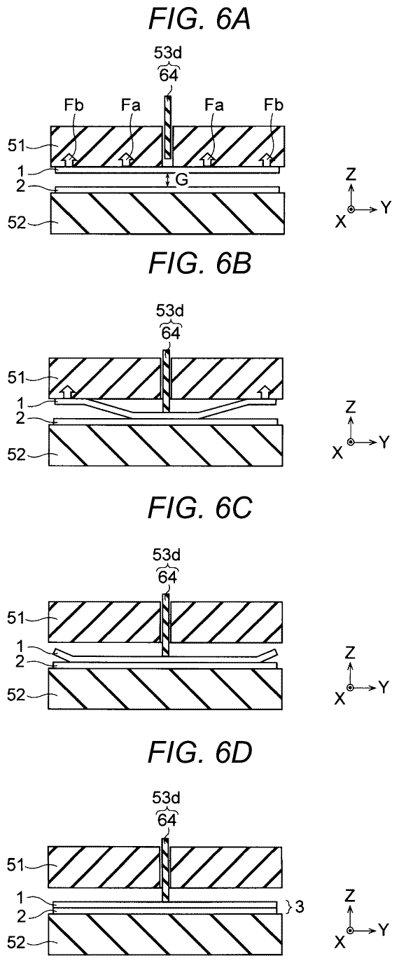

FIGS. 6A to 6D are sectional views illustrating an operation of the bonding apparatus according to the first embodiment. FIGS. 6A to 6D illustrate an aspect in which the upper wafer 1 held by the upper chuck 51 and the lower wafer 2 held by the lower chuck 52 are bonded.

FIG. 6A illustrates the upper wafer 1 and the lower wafer 2 before the bonding is started. In FIG. 6A, suction forces Fa acted on the upper wafer 1 from the suction tubes 62 (see FIG. 4) and suction forces Fb acted on the upper wafer 1 from the suction tubes 63 (see FIG. 4) are illustrated. From this viewpoint, the striker 53d does not come into contact with the upper wafer 1 and a pressurizing force is not acted on the upper wafer 1 from the striker 53d.

In FIG. 6A, a gap G between the upper wafer 1 and the lower wafer 2 before the start of the bonding is further illustrated. The gap G according to the embodiment corresponds to a distance between the lower surface of the upper wafer 1 and the upper surface of the lower wafer 2. The gap G illustrated in FIG. 6A is a distance between the center of the upper wafer 1 and the center of the lower wafer 2. The center of the upper wafer 1 is a portion on a central axis of the upper wafer 1 and the center of the lower wafer 2 is a portion on a central axis of the lower wafer 2.

The lower wafer 2 illustrated in FIG. 6A may be deformed by the loading platform 72. By executing the bonding in the state in which the lower wafer 2 is deformed, it is possible to correct the difference in the magnification between the upper wafer 1 and the lower wafer 2.

When the upper wafer 1 and the lower wafer 2 are bonded, the vacuum pump 66 (see FIG. 4) is stopped and the vacuuming from the suction tubes 62 is stopped. Thereafter, while the upper wafer 1 is sucked by the suction tubes 63, the upper wafer 1 is pressurized by the striker 53d (see FIG. 6B). In the embodiment, the striker 53d pressurizes the center of the upper wafer 1 with respect to the center of the lower wafer 2 and the suction tubes 63 suck portions other than the center of the upper wafer 1. Therefore, the bonding of the upper wafer 1 and the lower wafer 2 is progressed from the centers to the peripheries of the upper wafer 1 and the lower wafer 2. That is, contact regions of the upper wafer 1 and the lower wafer 2 spread from the centers to the peripheries of the upper wafer 1 and the lower wafer 2.

The progress of the bonding stops subsequently. This is referred to as a wait state. FIG. 6B illustrates the upper wafer 1 and the lower wafer 2 in the wait state.

When the bonding reaches the wait state, the bonding apparatus according to the embodiment stops the vacuum pump 67 (see FIG. 4) and stops the vacuuming from the suction tubes 63 in the state in which the upper wafer 1 is pressurized by the striker 53d. As a result, the bonding of the upper wafer 1 and the lower wafer 2 is further progressed by dropping the upper wafer 1 to the lower wafer 2 (see FIG. 6C).

In this way, the bonding of the upper wafer 1 and the lower wafer 2 is progressed until the ends of the upper wafer 1 and the lower wafer 2 are bonded (see FIG. 6D). FIG. 6D illustrates the bonded wafer 3 obtained by bonding the upper wafer 1 and the lower wafer 2.

Here, an operation of the control circuit 30 (see FIG. 2) according to the embodiment will be described.

The control circuit acquires a value of a warp amount of the upper wafer 1 before the bonding is started. As used herein, a warp amount of a wafer includes an amount of protrusion of a portion of the wafer (e.g., at the center of the wafer) relative to an edge of the wafer. Furthermore, the warp amount may be positive or negative, depending on a direction of the protrusion. The control circuit 30 determines a value of the gap G between the upper wafer 1 and the lower wafer 2 based on the value of the warp amount and determines a value (strength) of the pressurizing force of the striker 53d based on the value of the gap G.

The control circuit 30 sets the gap G between the upper wafer 1 and the lower wafer 2 to the determined value before the bonding is started. Then, as illustrated in FIGS. 6A to 6D, the upper wafer 1 and the lower wafer 2 are bonded by causing the control circuit 30 to control an operation of the bonding chamber 50. During the bonding, the control circuit 30 controls the pressurizing force of the striker 53d to equal the determined strength. The gap G between the upper wafer 1 and the lower wafer 2 is adjusted to the determined value at a time point at which the bonding is started (a time point illustrated in FIG. 6A).

According to the embodiment, by controlling the gap G and the pressurizing force, it is possible to accurately bond the upper wafer 1 and the lower wafer 2. Further details of the advantage will be described below.

### (2) Exposure and Bonding (Exposure Correction)

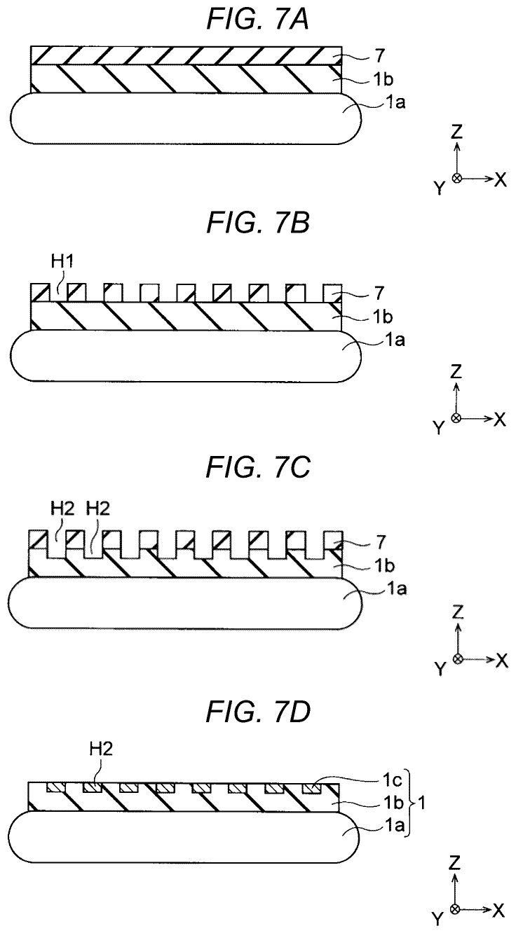

FIGS. 7A to 7D are sectional views illustrating a method of manufacturing the upper wafer 1 according to the first embodiment.

First, the interlayer insulating film 1b is formed on the wafer 1a and a resist layer 7 is formed on the interlayer insulating film 1b (see FIG. 7A). Subsequently, a pattern is formed in the resist layer 7 by lithography and etching (see FIG. 7B). As a result, a plurality of recess portions H1 in the resist layer 7 are formed.

Subsequently, a pattern of the resist layer 7 is transferred to the interlayer insulating film 1b by executing etching using the resist layer 7 as a mask (see FIG. 7C). As a result, a plurality of recess portions H2 are formed in the resist layer 7.

Subsequently, after the resist layer 7 is removed, the plurality of metal pads 1c are formed in the recess portions H2 (see FIG. 7D). The metal pads 1c are formed by forming a metal layer which is a material of the metal pads 1c on the interlayer insulating film 1b and applying a pattern to the surface of the metal layer by chemical mechanical polishing (CMP).

In this way, the upper wafer 1 illustrated in FIG. 1A is manufactured. The lower wafer 2 illustrated in FIG. 1B can be manufactured through processes illustrated in FIGS. 7A to 7D.

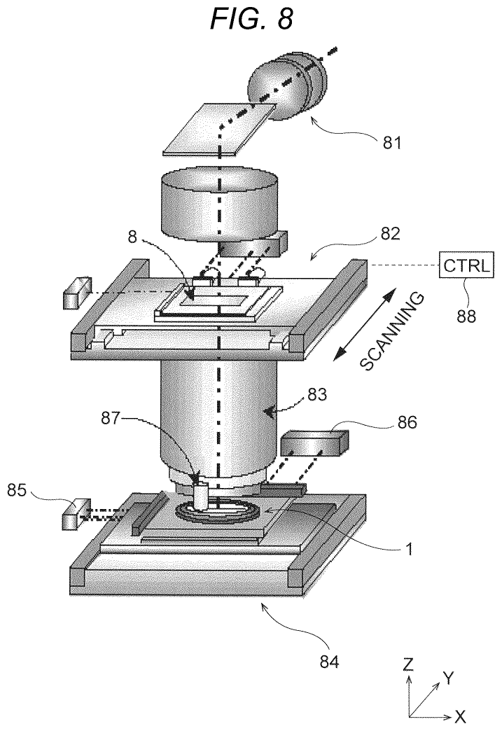

FIG. 8 is a perspective view illustrating a configuration of an exposure apparatus according to the first embodiment. In the embodiment, exposure when the upper wafer 1 and the lower wafer 2 are manufactured is executed by the exposure apparatus. For example, lithography in the process illustrated in FIG. 7B is executed by the exposure apparatus.

As illustrated in FIG. 8, the exposure apparatus according to the embodiment includes an illumination optical system 81, a table 82, a projection lens 83, a stage 84, an X axis interferometer 85, a Y axis interferometer 86, an off-axis microscope 87, and a control circuit 88. In FIG. 8, a reticle 8 loaded on the table 82 and the upper wafer 1 loaded on the stage 84 are further illustrated. Instead of the upper wafer 1, the lower wafer 2 may be loaded on the stage 84.

The illumination optical system 81 generates light for exposing the upper wafer 1. The reticle 8 on the table 82 is irradiated with light from the illumination optical system 81. The table 82 moves the reticle 8 so that the reticle 8 is scanned with the light. The light transmitted through the reticle 8 is incident on the upper wafer 2 on the stage 84 via the projection lens 83. In this way, the upper wafer 2 is exposed. The X axis interferometer 85, the Y axis interferometer 86, and the off-axis microscope 87 are used to measure an aspect of the exposure. An operation of the exposure apparatus according to the embodiment is controlled by the control circuit 88.

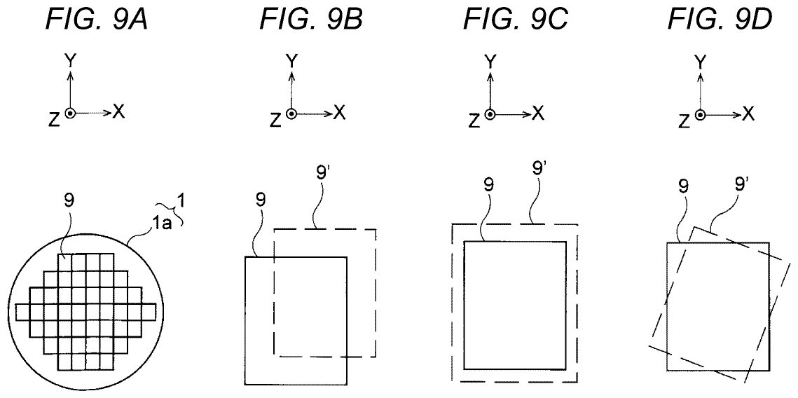

FIGS. 9A to 9D are plan views illustrating exposure correction according to the first embodiment.

In FIG. 9A, a plurality of shot regions 9 of the upper wafer 1 are illustrated. When the upper wafer 1 is exposed, the exposure is executed on each of the individual shot regions 9. When the shot region 9 is exposed, the exposure apparatus according to the embodiment executes exposure correction to change the shot region 9 to a shot region 9′. In exposure correction illustrated in FIG. 9B, the shot region 9 is shifted to the shot region 9′ as illustrated in FIGS. 9B to 9D. In exposure correction illustrated in FIG. 9C, the shot region 9 is expanded to the shot region 9′ (but may instead be reduced). In exposure correction illustrated in FIG. 9D, the shot region 9 is rotated to the shot region 9′. According to the embodiment, misalignment during the bonding of the upper wafer 1 and the lower wafer 2 is reduced through such exposure correction.

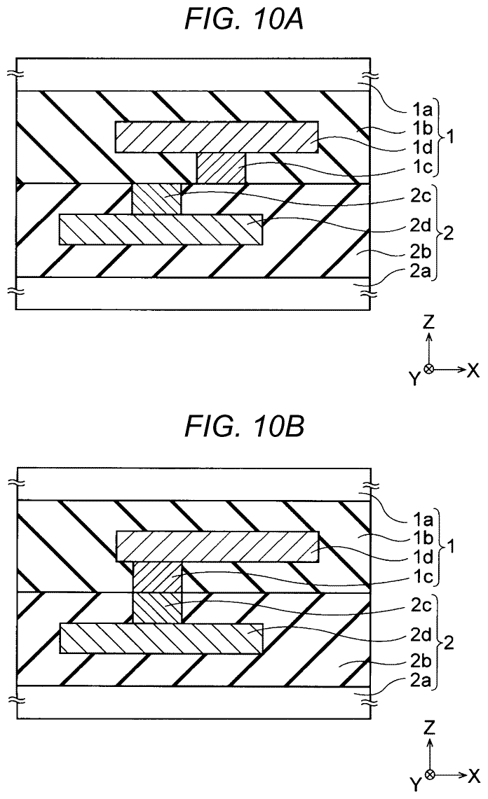

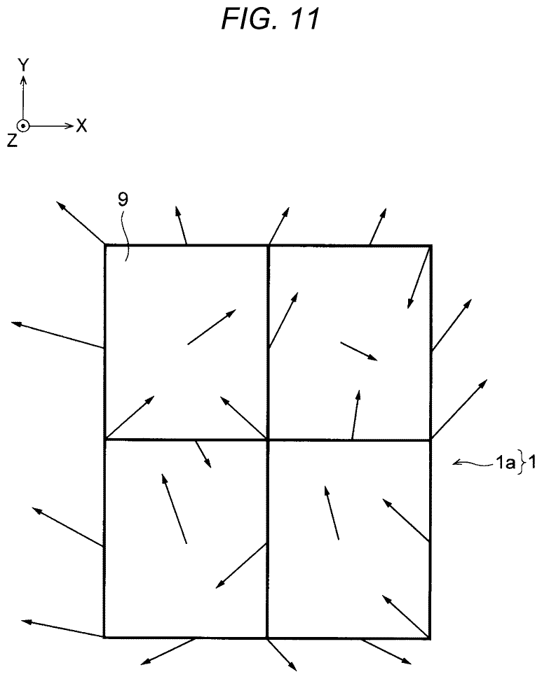

FIGS. 10A and 10B are sectional views illustrating exposure correction according to the first embodiment.

In FIG. 10A, the bonded upper wafer 1 and lower wafer 2 are illustrated. The upper wafer 1 includes the wafer 1a, the interlayer insulating film 1b, the metal pad 1c, and a wiring layer 1d. The metal pad 1c is formed on the lower surface of the wiring layer 1d. The lower wafer 2 includes the wafer 2a, the interlayer insulating film 2b, the metal pad 2c, and a wiring layer 2d. The metal pad 2c is formed on the upper surface of the wiring layer 2d. The same applies to FIG. 10B.

FIG. 10A illustrates the upper wafer 1 and the lower wafer 2 when no exposure correction is executed. In FIG. 10A, the metal pad 1c that is to be bonded to the metal pad 2c is not bonded to the metal pad 2c. That is, position deviation has occurred between the metal pads 1c and 2c.

FIG. 10B illustrates the upper wafer 1 and the lower wafer 2 after the exposure correction is executed. The metal pad 1c in FIG. 10B is formed by executing the exposure correction during the lithography of the process illustrated in FIG. 7B. Accordingly, the position of the metal pad 1c in FIG. 10B is different from the position of the metal pad 1c in FIG. 10A. As a result, in FIG. 10B, the metal pad 1c is bonded to the metal pad 2c. In this way, according to the embodiment, a positional deviation between the metal pads 1c and 2c is reduced through the exposure correction.

FIG. 11 is a plan view illustrating exposure correction according to the first embodiment.

In FIG. 11, the plurality of shot regions 9 of the upper wafer 1 are illustrated as in FIG. 9A. Arrows illustrated in FIG. 11 indicate positional deviations between ideal shot regions 9 and actual shot regions 9 of the upper wafer 1. The ideal shot regions 9 correspond to, for example, shot regions located in a lower layer of the actual shot regions 9. A size of the arrow indicates the magnitude of a positional deviation. FIG. 11 is also referred to as an exposure overlay (OL) map. On the other hand, a map related to the positional deviation during the bonding of the upper wafer 1 and the lower wafer 2 is referred to as a bonding OL map. A state in which an amount of positional deviation is relatively small is “good” and a state in which the amount of positional deviation is relatively large is “poor” in each OL map.

General exposure correction may be executed so that the positional deviation between the ideal shot regions 9 and the actual shot regions 9 of the upper wafer 1 is reduced. That is, the general exposure correction may be executed so that the arrows illustrated in FIG. 11 become smaller on average. On the other hand, the exposure correction according to the embodiment may be executed so that the positional deviation during the bonding of the upper wafer 1 and the lower wafer 2 is reduced. Accordingly, the exposure correction according to the embodiment may not be necessarily executed so that the arrows become smaller on average, and the arrows may instead become larger on average. Accordingly, even when the positional deviation between the ideal shot regions 9 and the actual shot regions 9 of the upper wafer 1 is expanded, the positional deviation during the bonding of the upper wafer 1 and the lower wafer 2 may be reduced. In other words, even while the exposure OL map becomes poor, the bonding OL map may become good. FIGS. 10A and 10B described above illustrate an example in which the positional deviation during the bonding of the upper wafer 1 and the lower wafer 2 is reduced.

### (3) Comparative Example

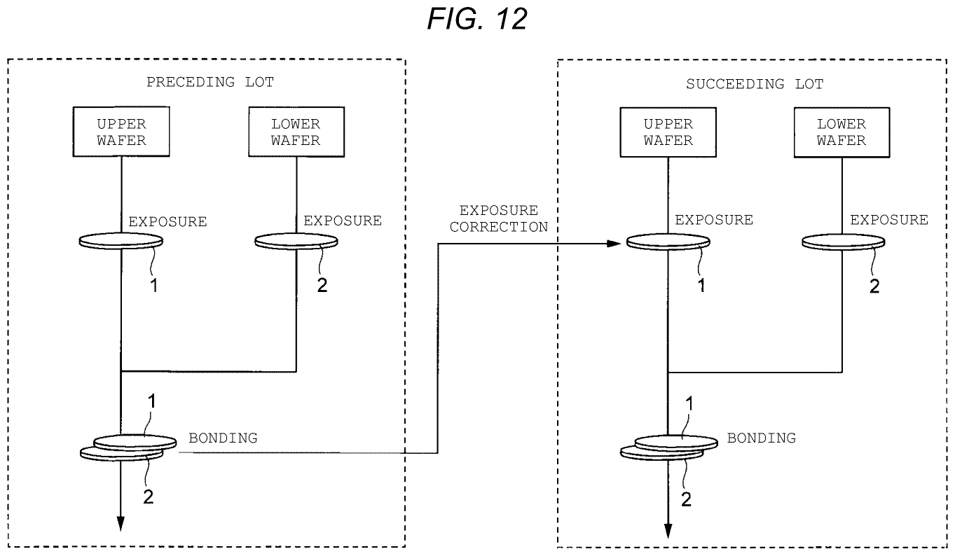

FIG. 12 is a schematic view illustrating a flow of exposure and bonding according to a comparative example.

According to the comparative example, a plurality of semiconductor devices are manufactured from a pair of upper wafer 1 and lower wafer 2. Hereinafter, the pair of wafers is referred to as a “wafer pair”. FIG. 12 illustrates a flow in which the plurality of semiconductor devices are manufactured from a wafer pair of a preceding lot, and then a plurality of semiconductor devices are manufactured from the pair of wafers of the succeeding lot.

First, the upper wafer 1 and the lower wafer 2 of the preceding lot are manufactured. At this time, the upper wafer 1 and the lower wafer 2 are exposed using the exposure apparatus in FIG. 8. For example, the exposure when the metal pads 1c of the upper wafer 1 and the metal pads 2c of the lower wafer 2 are formed is executed using the exposure apparatus. The exposure is executed so that the exposure OL map of the upper wafer 1 is good and the exposure OL map of the lower wafer 2 is also good.

Subsequently, the upper wafer 1 and the lower wafer 2 of the preceding lot are bonded. At this time, the upper wafer 1 and the lower wafer 2 are bonded using the bonding apparatus in FIG. 2. The exposure of the preceding lot is executed so that the exposure OL map of the upper wafer 1 is good and the exposure OL map of the lower wafer 2 is also good, as described above, which deteriorates the bonding OL map of the preceding lot in some cases. For example, as illustrated in FIG. 10A, the positional deviation between the metal pads 1c and 2c occurs in some cases.

Accordingly, when the upper wafer 1 and the lower wafer 2 of the succeeding lot are manufactured, the exposure correction of the succeeding lot is executed based on the bonding OL map of the preceding lot. For example, the exposure correction of the upper wafer 1 of the succeeding lot is executed so that the bonding OL map of the succeeding lot becomes good. In this case, the exposure of the succeeding lot is executed so that the exposure OL map of the upper wafer 1 becomes poor and the exposure OL map of the lower wafer 2 becomes good. Accordingly, it is possible to make the bonding OL map of the succeeding lot good. For example, as illustrated in FIG. 10B, it is possible to reduce the positional deviation between the metal pads 1c and 2c.

When the upper wafer 1 and the lower wafer 2 of the succeeding lot are manufactured, the upper wafer 1 and the lower wafer 2 are exposed using the exposure apparatus in FIG. 8. At this time, as described above, the exposure correction of the succeeding lot is executed based on the bonding OL map of the preceding lot. When the upper wafer 1 and the lower wafer 2 of the succeeding lot are bonded, the bonding of the upper wafer 1 and the lower wafer 2 is executed using the bonding apparatus in FIG. 2. According to the comparative example, the bonding OL map of the succeeding lot can be made good through the exposure correction of the succeeding lot.

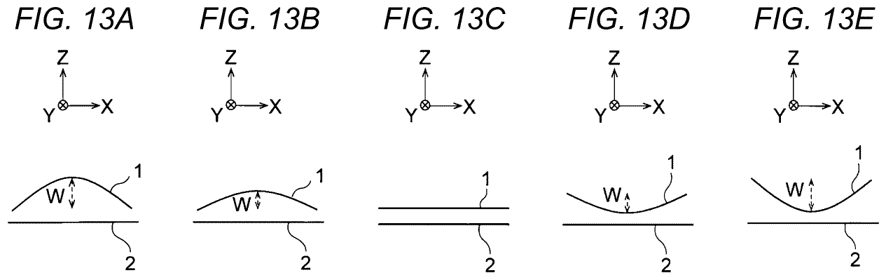

FIGS. 13A to 13E are sectional views illustrating details of bonding according to a comparative example.

In FIGS. 13A to 13E, five pairs of upper wafers 1 and lower wafers 2 are illustrated. In FIG. 13A, the upper wafer 1 is greatly warped in an upper convex form. In FIG. 13B, the upper wafer 1 is slightly warped in an upper convex form. In FIG. 13C, the upper wafer 1 is not warped. In FIG. 13D, the upper wafer 1 is slightly warped in a downward convex form. In FIG. 13E, the upper wafer 1 is greatly warped in a downward convex form. The lower wafer 2 is not warped in any of FIGS. 13A to 13E.

In each of FIGS. 13A, 13B, 13D, and 13E, a warp amount W of the upper wafer 1 is illustrated. Here, magnitude of the warp amount W is a maximum protrusion amount of the upper wafer 1 with respect to the edge of the upper wafer 1. For example, in FIG. 13A, the center of the upper wafer 1 protrudes most in the +Z direction with respect to the edge of the upper wafer 1, and the warp amount W is the difference between the Z coordinate of the center of the upper wafer 1 and the Z coordinate of the edge of the upper wafer 1. The same applies to FIGS. 13B, 13D, and 13E. A value of the warp amount W is defined such that the value is negative in FIGS. 13A and 13B, is zero in FIG. 13C, and is positive in FIGS. 13D and 13E. Accordingly, in FIGS. 13A to 13E, the warp amount W in FIG. 13A is the smallest and the warp amount W in FIG. 13E is the largest. The magnitude (absolute value) of the warp amount W is large in FIGS. 13A and 13E and is small in FIGS. 13B and 13D.

The bonding OL map of the upper wafer 1 and the lower wafer 2 changes in accordance with the warp amount W of the upper wafer 1. This is because in the bonding process illustrated in FIG. 6B, stress applied from the upper chuck 51 to the upper wafer 1 changes in accordance with the warp amount W of the upper wafer 1.

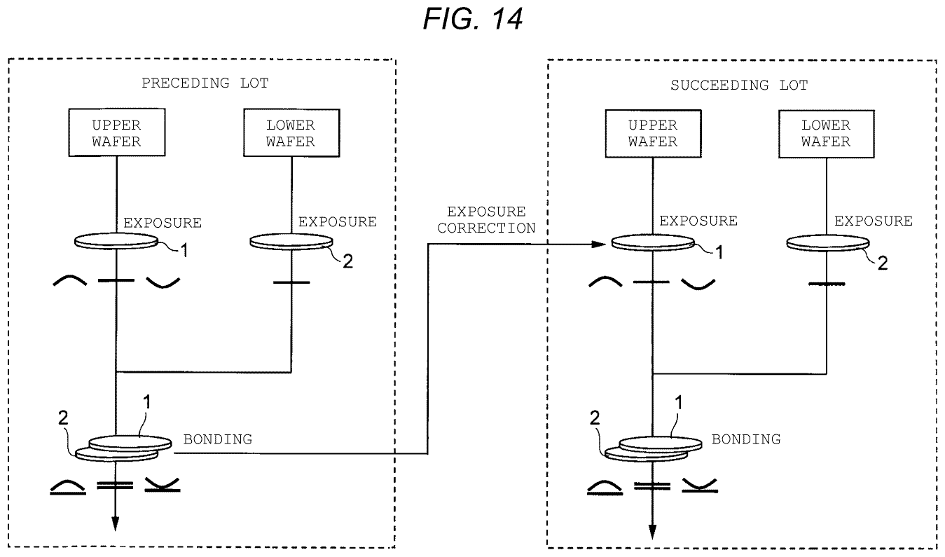

FIG. 14 is a schematic view illustrating a flow of exposure and bonding according to a comparative example.

As in FIG. 12, FIG. 14 illustrates a flow in which a plurality of semiconductor devices are manufactured from the pair of wafers of the preceding lot, and then a plurality of semiconductor devices are manufactured from the pair of wafers of the succeeding lot.

First, the upper wafer 1 and the lower wafer 2 of the preceding lot are manufactured. At this time, the upper wafer 1 and the lower wafer 2 are exposed so that the exposure OL map of the upper wafer 1 is good and the exposure OL map of the lower wafer 2 is also good.

Subsequently, the upper wafer 1 and the lower wafer 2 of the preceding lot are bonded. The exposure of the preceding lot is executed so that the exposure OL map of the upper wafer 1 is good and the exposure OL map of the lower wafer 2 is also good, as described above, which deteriorates the bonding OL map of the preceding lot in some cases.

Accordingly, when the upper wafer 1 and the lower wafer 2 of the succeeding lot are manufactured, the exposure correction of the upper wafer 1 of the succeeding lot is executed based on the bonding OL map of the preceding lot. In this case, the exposure of the succeeding lot is executed so that the exposure OL map of the upper wafer 1 becomes poor and the exposure OL map of the lower wafer 2 becomes good. Accordingly, it is possible to make the bonding OL map of the succeeding lot good.

In this case, the warp amount W of the upper wafer 1 of the preceding lot becomes a problem. FIG. 14 illustrates the upper wafer 1 of which the warp amount W is negative, zero, and positive as examples of the upper wafer 1 of the preceding lot. For example, when the warp amount W of the upper wafer 1 of the preceding lot is zero, exposure correction of the upper wafer 1 of the succeeding lot is appropriate for the upper wafer 1 of which the warp amount W is zero. Accordingly, when the warp amount W of the upper wafer 1 of the succeeding lot is zero, the bonding OL map of the succeeding lot becomes good through the exposure correction of the upper wafer 1 of the succeeding lot. However, when the warp amount W of the upper wafer 1 of the succeeding lot is not zero, there is concern of the bonding OL map of the succeeding lot not being good through the exposure correction of the upper wafer 1 of the succeeding lot.

Thus, in the embodiment, the succeeding wafer is subjected to not only the exposure correction but also the bonding correction. Accordingly, it is possible to handle the problem of the warp amount W of the upper wafer 1. The bonding correction according to the embodiment is executed by controlling the value of the gap G between the upper wafer 1 and the lower wafer 2, as described with reference to FIGS. 6A to 6D. Further details of the bonding correction will be described below.

### (4) Bonding Correction

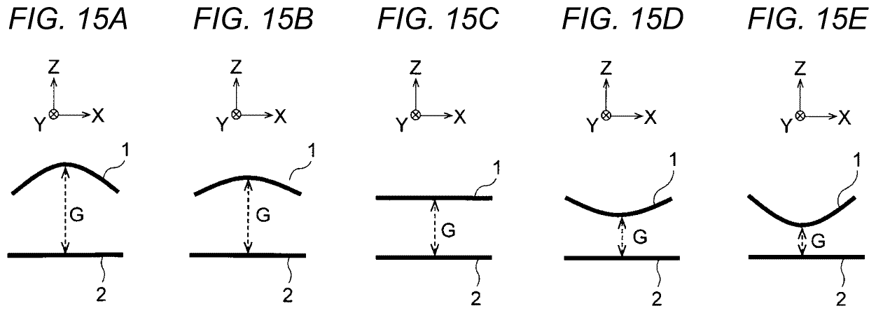

FIGS. 15A to 15E are sectional views illustrating details of bonding according to the first embodiment.

As in FIGS. 13A to 13E, in FIGS. 15A to 15E, five pairs of upper wafer 1 and lower wafer 2 are illustrated. In FIG. 15A, the upper wafer 1 is greatly warped in an upper convex form. In FIG. 15B, the upper wafer 1 is slightly warped in an upper convex form. In FIG. 15C, the upper wafer 1 is not warped. In FIG. 15D, the upper wafer 1 is slightly warped in a downward convex form. In FIG. 15E, the upper wafer 1 is greatly warped in a downward convex form. The lower wafer 2 is not warped in any of FIGS. 15A to 15E.

In FIGS. 15A to 15E, the gap G between the upper wafer 1 and the lower wafer 2 is further illustrated. The gap G according to the embodiment is a distance between the center of the upper wafer 1 and the center of the lower wafer 2. The bonding correction according to the embodiment is executed by controlling the value of the gap G.

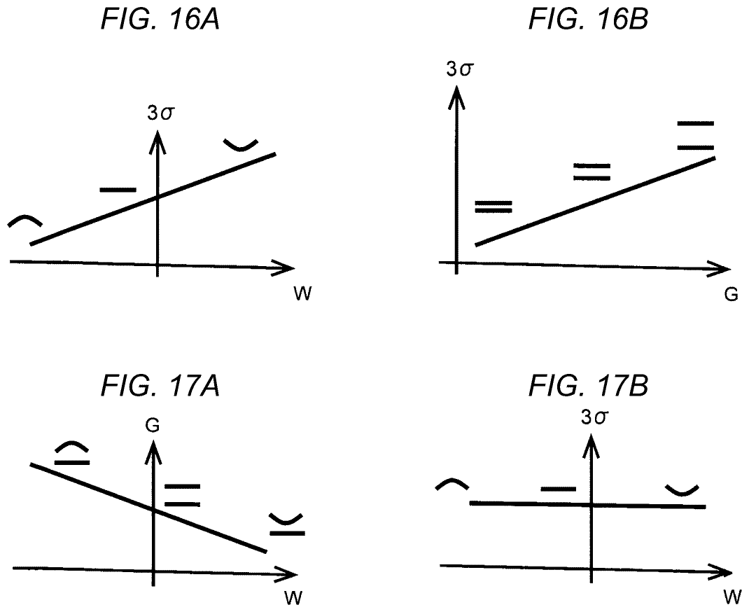

FIGS. 16A and 16B are graphs illustrating bonding correction according to the first embodiment.

In FIG. 16A, the horizontal axis represents the warp amount W of the upper wafer 1 and the vertical axis represents a 3σ value of the bonding OL map of the upper wafer 1 and the lower wafer 2. Here, σ indicates a standard deviation of an X component (or a Y component) of an arrow in the bonding OL map. The 3σ value indicates a variation in the X component (or Y component) with regard to the arrow in the bonding OL map. In the embodiment, the larger the warp amount W is, the larger the 3σ value of the bonding OL map is. Accordingly, when the warp amount W increases, the bonding OL map becomes poor. When the warp amount W decreases, the bonding OL map becomes good.

In FIG. 16B, the horizontal axis represents the gap G between the upper wafer 1 and the lower wafer 2 before start of the bonding (see FIG. 6A). The vertical axis represents the 3σ value of the bonding OL map of the upper wafer 1 and the lower wafer 2. In the embodiment, the larger the gap G is, the larger the 3σ value of the bonding OL map is. Accordingly, when the gap G increases, the bonding OL map becomes poor. When the gap G decreases, the bonding OL map becomes good.

FIGS. 17A and 17B are graphs illustrating bonding correction according to the first embodiment.

In FIG. 17A, the horizontal axis represents the warp amount W of the upper wafer 1 and the vertical axis represents the gap G between the upper wafer 1 and the lower wafer 2 before start of the bonding. The bonding correction according to the embodiment is executed, as illustrated in FIG. 17A. That is, the bonding correction according to the embodiment is executed so that the larger the warp amount W, the smaller the gap G is. In FIG. 17A, the gap G decreases as the warp amount W increases.

In FIG. 17B, a relation between the 3σ value and the warp amount W during execution of the bonding correction illustrated in FIG. 17A is illustrated. In this case, even when the warp amount W of the upper wafer 1 is changed, the 3σ value of the bonding OL map of the upper wafer 1 and the lower wafer 2 is constant. Accordingly, according to the embodiment, by executing the bonding correction illustrated in FIG. 17A, it is possible to inhibit an influence of the warp amount W on the bonding OL map. Accordingly, even when the upper wafer 1 is warped, the bonding OL map can be made good.

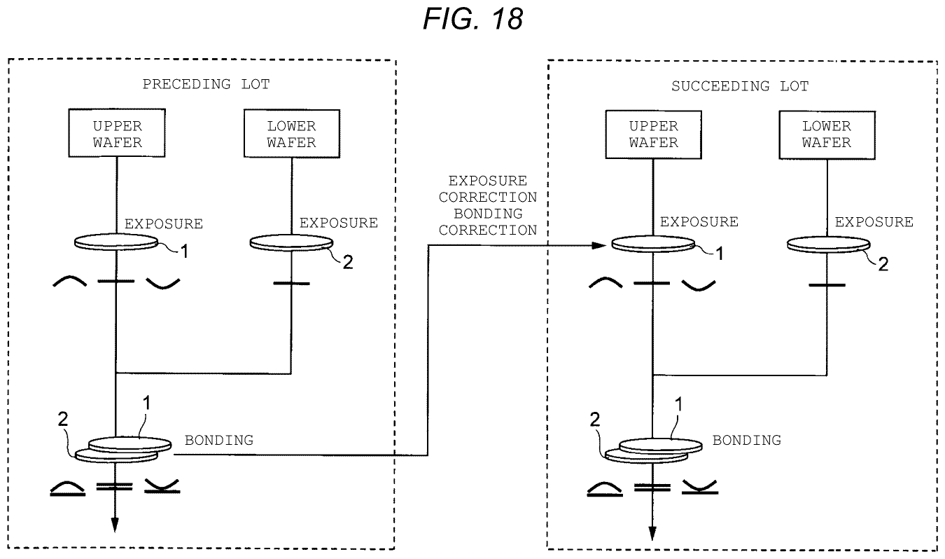

FIG. 18 is a schematic view illustrating a flow of exposure and bonding according to the first embodiment.

As in FIGS. 12 and 14, FIG. 18 illustrates a flow in which a plurality of semiconductor devices are manufactured from the pair of wafers of the preceding lot, and then a plurality of semiconductor devices are manufactured from the pair of wafers of the succeeding lot.

First, the upper wafer 1 and the lower wafer 2 of the preceding lot are manufactured. At this time, the upper wafer 1 and the lower wafer 2 are exposed using the exposure apparatus in FIG. 8. For example, the exposure when the metal pads 1c of the upper wafer 1 or the metal pads 2c of the lower wafer 2 are formed is executed using the exposure apparatus. The exposure is executed so that the exposure OL map of the upper wafer 1 is good and the exposure OL map of the lower wafer 2 is also good.

Subsequently, the upper wafer 1 and the lower wafer 2 of the preceding lot are bonded. At this time, the upper wafer 1 and the lower wafer 2 are bonded using the bonding apparatus in FIG. 2. The exposure of the preceding lot is executed so that the exposure OL map of the upper wafer 1 is good and the exposure OL map of the lower wafer 2 is also good, as described above, which deteriorates the bonding OL map of the preceding lot in some cases. For example, as illustrated in FIG. 10A, positional deviation between the metal pads 1c and 2c occurs in some cases.

Accordingly, when the upper wafer 1 and the lower wafer 2 of the succeeding lot are manufactured, the exposure correction of the succeeding lot is executed based on the bonding OL map of the preceding lot. For example, the exposure correction of the upper wafer 1 of the succeeding lot is executed so that the bonding OL map of the succeeding lot becomes good. In this case, the exposure of the succeeding lot is executed so that the exposure OL map of the upper wafer 1 becomes poor and the exposure OL map of the lower wafer 2 becomes good. Accordingly, it is possible to make the bonding OL map of the succeeding lot good. For example, as illustrated in FIG. 10B, the positional deviation between the metal pads 1c and 2c can be reduced.

In this case, the warp amount W of the upper wafer 1 of the preceding lot becomes a problem. FIG. 18 illustrates the upper wafer 1 of which the warp amount W is negative, zero, and positive as examples of the upper wafer 1 of the preceding lot. For example, when the warp amount W of the upper wafer 1 of the preceding lot is zero, exposure correction of the upper wafer 1 of the succeeding lot is appropriate for the upper wafer 1 of which the warp amount W is zero. Accordingly, when the warp amount W of the upper wafer 1 of the succeeding lot is zero, the bonding OL map of the succeeding lot becomes good through the exposure correction of the upper wafer 1 of the succeeding lot. However, when the warp amount W of the upper wafer 1 of the succeeding lot is not zero, there is concern of the bonding OL map of the succeeding lot not being good through the exposure correction of the upper wafer 1 of the succeeding lot.

Thus, when the upper wafer 1 and the lower wafer 2 of the succeeding lot are bonded, the bonding correction of the succeeding lot is executed based on the warp amount W of the upper wafer 1 of the succeeding lot. For example, the bonding correction of the succeeding lot is executed so that the larger the warp amount W is, the smaller the above-described gap G is. Accordingly, even when the upper wafer 1 of the succeeding lot is warped, the bonding OL map of the succeeding lot can be made good.

When the upper wafer 1 and the lower wafer 2 of the succeeding lot are manufactured, the upper wafer 1 and the lower wafer 2 are exposed using the exposure apparatus in FIG. 8. At this time, as described above, the exposure correction of the succeeding lot is executed based on the bonding OL map of the preceding lot. When the upper wafer 1 and the lower wafer 2 of the succeeding lot are bonded, the upper wafer 1 and the lower wafer 2 are bonded using the bonding apparatus in FIG. 2. At this time, as described above, the bonding correction of the succeeding lot is executed based on the warp amount W of the upper wafers 1 of the succeeding lot. According to the embodiment, even when the upper wafer 1 of the succeeding lot is warped through the exposure correction and the bonding correction of the succeeding lot, the bonding OL map of the succeeding lot is made good.

The exposure correction according to the embodiment is executed with common content on all the pairs of wafers of the succeeding lot. This is because the bonding OL map of the preceding lot used for the exposure correction is common for all the pairs of wafers of the succeeding lot. On the other hand, the bonding correction according to the embodiment is executed differently on the pairs of wafers of the succeeding lot. This is because the warp amount W of the upper wafer 1 of the succeeding lot is different for each pair of wafers of the succeeding lot. Here, a relational formula between the gap G and the warp amount W according to the embodiment is common for all the pairs of wafers of the succeeding lot. This relational formula is given in the form of FIG. 17A. Details of the relational formula will be described below.

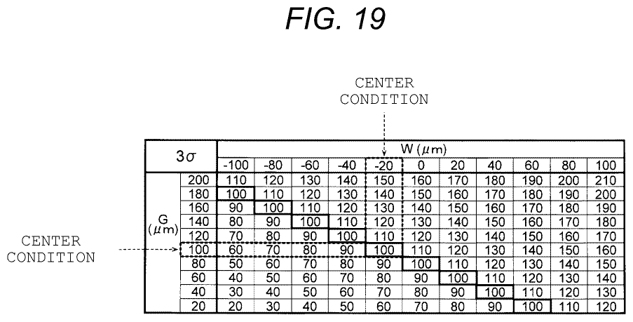

FIG. 19 is a table illustrating bonding correction according to the first embodiment.

FIG. 19 illustrates the 3σ value of the bonding OL map when the warp amount W of the upper wafer 1 is a predetermined value when the upper wafer 1 and the lower wafer 2 are bonded and when the gap G between the upper wafer 1 and the lower wafer 2 is adjusted to a predetermined value. For example, when the warp amount W is −40 μm and the gap G is adjusted to 60 μm, the 3σ value is 70 nm.

The 3σ value illustrated in FIG. 19 is 100 nm under a center condition. Specifically, the 3σ value illustrated in FIG. 19 is 100 nm when the warp amount W is −20 μm and the gap G is adjusted to 100 μm.

The bonding correction according to the embodiment is executed so that the 3σ value is 100 nm. For example, when the warp amount W is −40 μm, the gap G is adjusted to 120 μm. In FIG. 19, fields where the 3σ value is 100 nm are indicated by a thick border. These fields correspond to a straight line illustrated in FIG. 17A.

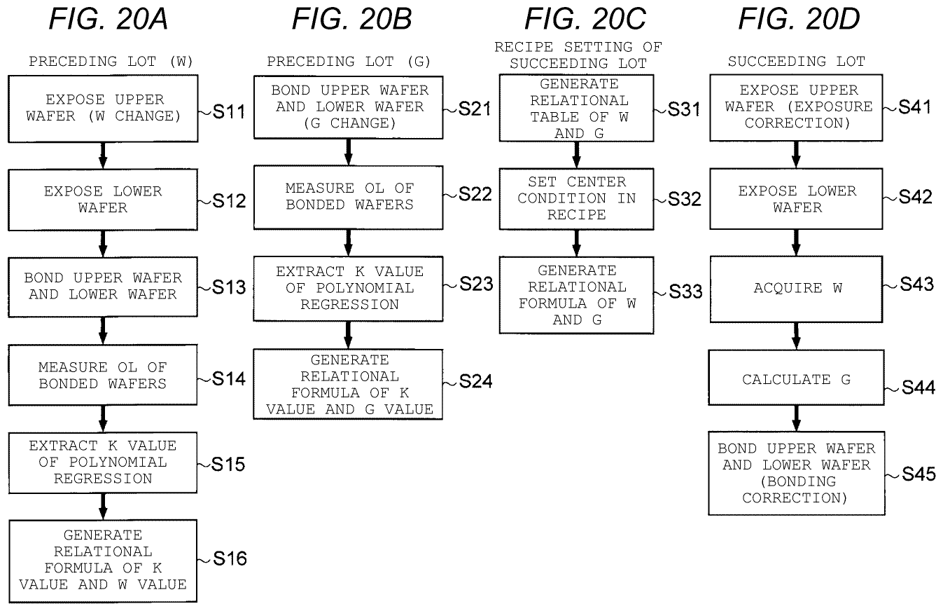

FIGS. 20A to 20D are flowcharts illustrating a method of manufacturing a semiconductor device according to the first embodiment.

FIG. 20A illustrates a flow related to the exposure and the bonding of the preceding lot. The exposure and the bonding are executed using the exposure apparatus of FIG. 8 and the bonding apparatus of FIG. 2.

First, the plurality of upper wafers 1 are manufactured from the plurality of wafers 1a. At this time, for example, when the plurality of metal pads 1c are formed above each wafer 1a, the exposure is executed using the exposure apparatus (step S11). In the embodiment, the upper wafers 1 are manufactured so that upper wafers 1 have different warp amounts W. Each upper wafer 1 may be warped due to warping of the original wafer 1a or may be warped due to an influence of the metal pads 1c. The same applies to each lower wafer 2.

Subsequently, the plurality of lower wafers 2 are manufactured from the plurality of wafers 2a. At this time, for example, when the plurality of metal pads 2c are formed above each wafer 2a, the exposure is executed using the exposure apparatus (step S12). In the embodiment, the lower wafer 2 is manufactured so that the lower wafer 2 has the same warp amount.

Subsequently, the upper wafer 1 and the lower wafer 2 are bonded by the bonding apparatus for each pair of wafers, and thus a plurality of bonded wafers 3 are manufactured (step S13). In this case, the gap G between the upper wafer 1 and the lower wafer 2 before start of the bonding is adjusted to the same value for all pairs of wafers.

Subsequently, the bonding OL of the bonded wafer 3 is measured (step S14). Subsequently, values (K values) of predetermined coefficients of polynomial regression are extracted from measurement data of the bonding OL of the bonded wafer 3 (step S15). For example, K17 and K18 of two coefficients of the polynomial regression are extracted. Subsequently, a relational formula between the K value and the warp amount W is generated using the K values extracted from the bonded wafer 3 and the warp amount W of the upper wafer 1 in the bonded wafer 3 (step S16). The processes of steps S14 to S16 may be executed automatically by a sensor or an apparatus such as a computer. In this way, the relational formula between the K value and the warp amount W according to the embodiment is generated based on results of executing exposure and bonding.

In a flow (FIG. 20D) of the succeeding lot to be described below, a value of a positional correction amount which is an amount with which an exposure position of the upper wafer 1 can be corrected before exposure of the upper wafer 1 is determined. An example of the positional correction amount is a coefficient of the polynomial regression (for example, K17 or K18). In the embodiment, by correcting the value of the coefficient of the polynomial regression related to the upper wafer 1, it is possible to correct the exposure position of the upper wafer 1. When the upper wafer 1 is exposed, the positional correction amount is controlled to the determined value. In this way, the exposure correction of the upper wafer 1 is executed.

The number of coefficients of the polynomial regression used as the positional correction amounts may be one or more. The positional correction amounts may be values other than the coefficients of the polynomial regression such as coefficients of a Zernike polynomial. The coefficients of the polynomial regression or the Zernike polynomial can be used to correct the exposure position of the upper wafer 1 and can also be used to correct the bonding position of the upper wafer 1 with respect to the lower wafer 2.

FIG. 20B illustrates another flow related to the exposure and the bonding of the preceding lot. The exposure and the bonding are executed using the exposure apparatus of FIG. 8 and the bonding apparatus of FIG. 2.

First, the plurality of upper wafers 1 and the plurality of lower wafers 2 are manufactured and the upper wafer 1 and the lower wafer 2 are bonded by the bonding apparatus for each pair of wafers to manufacture a plurality of bonded wafers 3 (step S21). In this case, the gap G between the upper wafer 1 and the lower wafer 2 before start of the bonding is adjusted to another value for each pair of wafers. The upper wafer 1 is manufactured so that the upper wafer 1 has the same warp amount W. Similarly, the lower wafer 2 is manufactured so that the lower wafer 2 has the same warp amount W.

Subsequently, the bonding OL of the bonded wafer 2 is measured (step S22). Subsequently, values (K values) of predetermined coefficients of polynomial regression are extracted from the measurement data of the bonding OL of the bonded wafer 3 (step S23). For example, values of two coefficients K17 and K18 of the polynomial regression are extracted. Subsequently, a relational formula between the K value and the gap G is generated using the K values extracted from the bonded wafer 3 and the above-described gap G related to the bonded wafer 3 (step S24). The processes of steps S22 to S24 may be executed automatically by a sensor or an apparatus such as a computer. In this way, the relational formula between the K value and the gap G according to the embodiment is generated based on results of executing exposure and bonding.

FIG. 20C illustrates a flow in which a recipe of the succeeding lot is set based on the preceding lot.

First, a relational table between the warp amount W and the gap G is generated using the relational formula between the K value and the warp amount W generated in step S16 and the relational formula between the K value and the gap G generated in step S24 (step S31). As a result, the table illustrated in FIG. 19 is generated.

Subsequently, the center conditions of the relational table are set in the recipe (step S32). The center conditions have been described with reference to FIG. 19.

Subsequently, the relational formula between the warp amount W and the gap G is generated based on the relational table and the center conditions (step S33). The relational formula is generated, for example, so that the 3σ value is 100 nm when the warp amount W and the gap G satisfy the relational formula, as indicated by the thick borders in FIG. 19. According to the embodiment, the bonding correction is executed using the relational formula determined in advance. The processes of steps S31 to S33 may be executed manually by a person or may be executed automatically by an apparatus such as a computer.

FIG. 20D illustrates a flow related to the exposure and the bonding of the succeeding lot. The exposure and the bonding are executed using the exposure apparatus in FIG. 8 and the bonding apparatus in FIG. 2.

First, the upper wafer 1 is manufactured from the wafer 1a. At this time, when the plurality of metal pads 1c are formed above each wafer 1a, the exposure is executed using the exposure apparatus (step S41). During the exposure, the exposure correction is executed based on the bonding OL map of the preceding lot. The exposure correction is executed in the aspect described with reference to FIG. 18. The exposure correction is controlled by the control circuit 88 in the exposure apparatus.

Subsequently, the lower wafer 2 is manufactured from the wafer 2a. At this time, for example, when the plurality of metal pads 2c are formed above each wafer 2a, the exposure is executed using the exposure apparatus (step S42).

Subsequently, the value of the warp amount W of the upper wafer 1 is acquired (step S43). The value of the warp amount W is measured using the bonding apparatus under the control of the control circuit 30 or is inputted to the bonding apparatus by an external measurement device that measures the warp amount W.

Subsequently, using the relational formula generated in step S33, the value of the gap G is calculated based on the value of the warp amount W acquired in step S43 (step S44). The value of the gap G is calculated by the control circuit 30. In this case, the relational formula may be stored in advance in a storage of the bonding apparatus or may be stored in advance in a storage of an apparatus with which the bonding apparatus communicates.

Subsequently, the upper wafer 1 and the lower wafer 2 are bonded by the bonding apparatus to manufacture the bonded wafer 3 (step S45). At this time, the gap G between the upper wafer 1 and the lower wafer 2 before start of the bonding is adjusted to the value calculated in step S44. In this way, the bonding correction is executed based on the warp amount W of the upper wafer 1. The bonding correction is controlled by the control circuit 30.

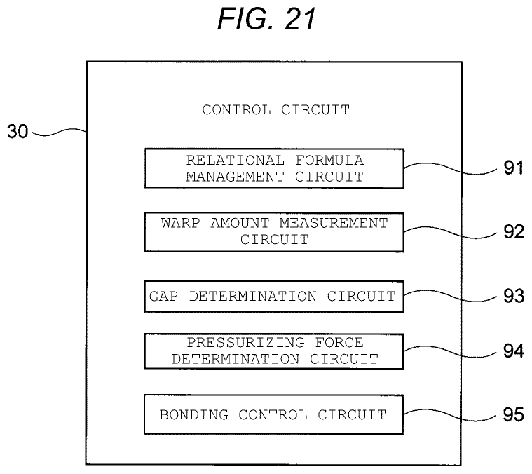

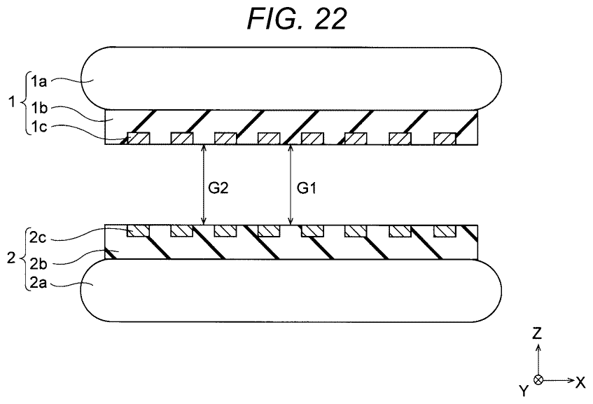

FIG. 21 is a block diagram illustrating a functional configuration of the control circuit 30 according to the first embodiment.

As illustrated in FIG. 21, the control circuit 30 includes a relational formula management circuit 91, a warp amount measurement circuit 92, a gap determination circuit circuit 93, a pressurizing force determination circuit 94, and a bonding control circuit 95. Each of the functional blocks (91 to 95) may be implemented directly by hardware or may be implemented by software running on hardware.

The relational formula management circuit 91 manages the relational formula between the warp amount W and the gap G. The relational formula management circuit 91 acquires the relational formula from the storage before step S44 of FIG. 20D is executed. The storage may be provided in the bonding apparatus or may be provided in an apparatus with which the bonding apparatus communicates.

The warp amount measurement circuit 92 acquires the value of the warp amount W of the upper wafer 1 in step S43 of FIG. 20D. The warp amount measurement circuit 92 acquires the value of the warp amount W of the upper wafer 1 by controlling a measurement device provided in the bonding apparatus or by receiving the value of the warp amount W from an external measurement device that measures the warp amount W.

The gap determination circuit 93 determines the value of the gap G based on the value of the warp amount W in step S44 of FIG. 20D. The gap determination circuit 93 calculates the value of the gap G from the value of the warp amount W measured by the warp amount measurement circuit 92, based on the relational formula managed by the relational formula management circuit 91.

The pressurizing force determination circuit 94 determines the strength of the pressurizing force for pressurizing the upper wafer 1 by the striker 53d based on the value of the gap G, before step S45 of FIG. 20D is executed. For example, the strength of the pressurizing force may be determined so that the pressurizing force increases as the gap G increases. In this case, when the value of the gap G determined by the gap determination circuit 93 is small, a small value is determined as the strength of the pressurizing force. Conversely, when the value of the gap G determined by the gap determination circuit 93 is large, a large value is determined as the strength of the pressurizing force. According to the embodiment, by determining the strength of the pressurizing force in this way, the upper wafer 1 is pressurized with an appropriate pressurizing force.

The bonding control circuit 95 controls the bonding and the bonding correction in step S45 of FIG. 20D. The bonding control circuit 95 controls the gap G between the upper wafer 1 and the lower wafer 2 before start of the bonding to become the value determined by the gap determination circuit 93. The bonding control circuit 95 controls the pressurizing force for pressurizing the upper wafer 1 by the striker 53d during the bonding to equal the strength determined by the pressurizing force determination circuit 94. Accordingly, the bonding and the bonding correction are appropriately executed.

The functional blocks may be implemented by, for example, a computer program causing a processor of the control circuit 30 to execute the processes of the functional blocks. In this case, the control circuit 30 includes a computer-readable recording medium in which the program is provided. All or part of the program may be downloaded from a network to the recording medium.

FIG. 22 is a sectional view illustrating a method of manufacturing a semiconductor device according to a modification of the first embodiment.

In FIG. 22, gaps G1 and G2 are indicated as examples of the gap G. The gap G1 is a gap between the center of the upper wafer 1 and the center of the lower wafer 2. The gap G2 is a gap between a portion other than the center of the upper wafer 1 and a portion other than the center of the lower wafer 2. In this way, the gap G according to the embodiment may be defined with the centers of the upper wafer 1 and the lower wafer 2 or may be defined with the portions other than the centers of the upper wafer 1 and the lower wafer 2.

In this way, the control circuit 30 according to the modification determines the value of the gap G between the upper wafer 1 and the lower wafer 2 based on the value of the warp amount W of the upper wafer 1 and controls the gap G to the determined value before the bonding of the upper wafer 1 and the lower wafer 2. Accordingly, according to the embodiment, even when the upper wafer 1 is in the warped state, the upper wafer 1 and the lower wafer 2 are appropriately bonded. When the exposure correction of the upper wafer 1 is executed and the upper wafer 1 is in a warped state, it is possible to implement appropriate bonding through the bonding correction of the upper wafer 1 and the lower wafer 2.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing apparatus comprising a control circuit configured to:
acquire, for a pair of substrates including a first substrate and a second substrate, a warp amount of the first substrate, the warp amount of the first substrate including an amount of protrusion of a portion of the first substrate relative to an edge of the first substrate;
determine a desired size for a gap between the first and second substrates based on the acquired warp amount; and
control a chuck movement device to move one of the first and second substrates to adjust the gap to the determined size before the first and second substrates are bonded.

2. The semiconductor manufacturing apparatus according to claim 1, wherein the control circuit uses a relational formula that is based on both gap sizes and warp amounts to determine the desired size for the gap based on the acquired warp amount.

3. The semiconductor manufacturing apparatus according to claim 1, wherein the control circuit determines the desired size for the gap in a manner that decreases the desired size for the gap based on an increase in the acquired warp amount.

4. The semiconductor manufacturing apparatus according to claim 1, wherein the desired size for the gap is based on a line between a center of the first substrate and a center of the second substrate.

5. The semiconductor manufacturing apparatus according to claim 1, wherein the control circuit is further configured to:
determine a strength of a pressurizing force for pressurizing the first substrate, based on the desired size for the gap; and
control a pushing device to apply the pressurizing force at the determined strength by pushing against the first substrate, when the first and second substrates are bonded.

6. The semiconductor manufacturing apparatus according to claim 5, wherein the control circuit determines the strength of the pressurizing force for pressurizing a center of the first substrate.

7. The semiconductor manufacturing apparatus according to claim 5, wherein the first substrate is bonded to an upper surface of the second substrate.

8. The semiconductor manufacturing apparatus according to claim 1, further comprising:
a bonding chamber in which the first and second substrates are bonded under control of the control circuit.

9. The semiconductor manufacturing apparatus according to claim 8, wherein the bonding chamber includes a suction device connected to vacuum pumps for holding the first substrate and a pushing device that pressurizes the first substrate by pushing against the first substrate to apply a pressurizing force.

10. The semiconductor manufacturing apparatus according to claim 8,
wherein the bonding chamber includes a first support device that supports a chuck holding the first substrate and a second support device that supports a chuck holding the second substrate, and
wherein the gap is adjusted to the determined size by the control circuit controlling the first support device.

11. A method of manufacturing a semiconductor device, the method comprising:
acquiring, for a pair of substrates including a first substrate and a second substrate, a warp amount of the first substrate, the warp amount of the first substrate including an amount of protrusion of a portion of the first substrate relative to an edge of the first substrate;
determining a desired size for a gap between the first and second substrates based on the acquired warp amount; and
controlling a chuck movement device to move one of the first and second substrates to adjust the gap to the determined size before the first and second substrates are bonded.

12. The method of manufacturing a semiconductor device according to claim 11, wherein a relational formula that is based on both gap sizes and warp amounts is used to determine the desired size for the gap based on the acquired warp amount.

13. The method of manufacturing a semiconductor device according to claim 11, wherein the desired size for the gap is determined in a manner that decreases the desired size for the gap based on an increase in the acquired warp amount.

14. The method of manufacturing a semiconductor device according to claim 11, further comprising:
determining a strength of a pressurizing force that pressurizes the first substrate by pushing against the first substrate, based on the desired size for the gap; and
causing the pressurizing force to equal the determined strength when the first and second substrates are bonded.

15. The method of manufacturing a semiconductor device according to claim 11, further comprising:
bonding the first and second substrates while causing the gap to be adjusted to the determined size.

16. The method of manufacturing a semiconductor device according to claim 11, further comprising:
determining a positional correction amount that is an amount that an exposure position of the first substrate is correctable, before exposing the first substrate to light; and
causing the determined positional correction amount to be applied to the first substrate when the first substrate is exposed,
wherein the first and second substrates are bonded after the first substrate is exposed.

17. The method of manufacturing a semiconductor device according to claim 16,
wherein a first relational formula that is based on both gap sizes and warp amounts is used to determine the desired size for the gap based on the acquired warp amount, and
wherein the first relational formula is generated based on (1) a second relational formula that is based on both warp amounts and positional correction amounts and (2) a third relational formula that is based on both gap sizes and positional correction amounts.

18. The method of manufacturing a semiconductor device according to claim 17, wherein the second relational formula and the third relational formula are generated based on results of executing exposure and bonding.

19. The method of manufacturing a semiconductor device according to claim 16, wherein the positional correction amount is a coefficient of a polynomial regression.

20. The method of manufacturing a semiconductor device according to claim 16, wherein the positional correction amount is a coefficient of a Zernike polynomial.
